(19) United States
(12) Patent Application Publication
(10) Pub. No.: US 2025/0351411 A1
(43) Pub. Date: Nov. 13, 2025

(54) TRANSISTOR PRODUCED USING IMPROVED METAL OXIDE PROCESS

(71) Applicant: Taiwan Semiconductor Manufacturing Company, LTD., Hsinchu (TW)

(72) Inventors: Yen-Chieh Huang, Changhua County (TW); Huai-Ying Huang, Jhonghe (TW); Yu-Chuan Shih, Hsinchu (TW); Chun-Chieh Lu, Taipei (TW); Wei-Gang Chiu, New Taipei (TW); I-Che Lee, Taipei (TW); Yu-Ming Lin, Hsinchu (TW)

(21) Appl. No.: 18/659,151

(22) Filed: May 9, 2024

(51) Int. Cl. H01L 29/66; H01L 21/02; H01L 29/51; H01L 29/78

(52) U.S. Cl. CPC H10D 30/0415; H01L 21/02186; H01L 21/02194; H01L 21/02244; H10D 30/701; H10D 64/685; H10D 64/689; H10D 64/691

(57) ABSTRACT

A method of fabricating a device includes forming a first layer. The first layer may be a ferroelectric layer if the device is a ferroelectric field effect transistor (FeFET), or a gate dielectric layer if the device is a transistor. Alternatively, the first layer may be a channel of the device. A metal oxide layer is formed on the first layer by depositing a metal layer on the first layer by physical vapor deposition followed by exposing the metal layer to ozone or ozone plasma. A second layer is formed on the metal oxide layer. The forming of the metal oxide layer may further include, prior to the depositing of the metal layer, exposing the first layer to ozone or ozone plasma. The metal layer may be a titanium layer.

### BACKGROUND

The following relates to fabrication of semiconductor devices that include at least one titanium oxide layer, to transistors with at least one titanium oxide layer, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of a ferroelectric field effect transistor (FeFET) including two titanium oxide layers, and further diagrammatically depicts a flow process for forming each of the titanium oxide layers.

FIG. 2 diagrammatically illustrates a top view of the FeFET of FIG. 1.

FIG. 3 diagrammatically illustrates a workflow for fabricating a FeFET.

FIGS. 4A, 4B, 4C, and 4D diagrammatically illustrate side sectional views of a FeFET-under-fabrication at successive stages of the workflow of FIG. 3, including forming two titanium oxide layers using the flow process diagrammatically depicted in FIG. 1.

FIG. 5 diagrammatically illustrates a side sectional view of a bottom-gate thin-film transistor (TFT) including two titanium oxide layers each formed using the flow process diagrammatically depicted in FIG. 1.

FIG. 6 diagrammatically illustrates a bottom-gate FeFET including two titanium oxide layers each formed using the flow process diagrammatically depicted in FIG. 1.

FIG. 7 diagrammatically illustrates top-gate TFT including a titanium oxide layer formed using the flow process diagrammatically depicted in FIG. 1.

FIG. 8 diagrammatically illustrates top-gate FeFET including a ferroelectric layer and a titanium oxide layer formed using the flow process diagrammatically depicted in FIG. 1.

FIG. 9 diagrammatically illustrates a double-gate TFT including two titanium oxide layers each formed using the flow process diagrammatically depicted in FIG. 1.

FIG. 10 diagrammatically illustrates a double-gate FeFET including two titanium oxide layers each formed using the flow process diagrammatically depicted in FIG. 1.

FIG. 11 diagrammatically illustrates a three-dimensional (3D) or vertical field effect transistor (FET) which may be a TFT or FeFET, and that includes including a titanium oxide layer formed using the flow process diagrammatically depicted in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Inclusion of a thin metal oxide interface layer on the channel of various types of transistors such as thin-film transistor (TFT) or ferroelectric field effect transistor (FeFET) provides certain performance benefits. For example, a thin titanium oxide interface layer between the ferroelectric layer and the channel of a FeFET can boost device endurance (number of program/erase cycles, i.e., PRG/ERS cycles), increase the memory window (MW) and ferroelectric polarization (2Pr), and increase the on-current (Ion).

However, formation of the titanium oxide layer increases transistor fabrication workflow complexity and time. Atomic layer deposition (ALD) is employed to form the titanium oxide layer. A monolayer of titanium oxide is deposited by first forming a titanium monolayer by chemical vapor deposition using a titanium precursor such as high purity tetrakis(diethylamido)titanium(IV), tetrakis(dimethylamido)titanium(IV), tetrakis(ethylmethylamido)titanium(IV), titanium(IV) diisopropoxidebis(2,2,6,6-tetramethyl-3,5-heptanedionate), titanium(IV) isopropoxide, or titanium tetrachloride. The titanium deposition by CVD is self-limiting to produce a monolayer of titanium. This is then followed by an ozone treatment to oxidize the titanium monolayer, followed by a nitrogen purge. This ALD cycle of titanium monolayer deposition, ozone treatment, and nitrogen purge is repeated to form each successive monolayer of titanium oxide until the desired thickness of the final titanium oxide layer is obtained. Hence, the ALD deposition of titanium oxide is costly and time consuming due to low deposition rate (a result of many ALD cycles providing monolayer-by-monolayer deposition), and it is difficult to control the titanium-to-oxygen (Ti—O) ratio. The latter Ti—O ratio has a significant impact on transistor performance.

In embodiments disclosed herein, a different approach is used for forming the titanium oxide layer (or other metal oxide interface layer) of a TFT, FeFET, or other transistor. In this approach, a titanium layer is formed by physical vapor deposition (PVD) and the titanium layer is turned into a titanium oxide layer. In one suitable approach, the titanium layer is formed by PVD and is then exposed to ozone or ozone plasma. Advantageously, this entails only a single cycle, that is, a single PVD deposition of a single titanium layer (or other metal layer) which is then oxidized by the ozone or ozone plasma exposure. Such a concise process is achieved because the physical vapor deposition of the titanium is not self-limited to a single monolayer of titanium. Rather, a thicker titanium layer (compared with the titanium monolayer obtained in a single cycle of ALD) can be deposited by physical vapor deposition (with the thickness controlled by the PVD deposition time), followed by ozone or ozone plasma exposure that oxidizes the thicker titanium layer to provide the final titanium oxide interface layer. Moreover, precise control of the Ti—O ratio is obtainable by controlling the time of the ozone or ozone plasma exposure.

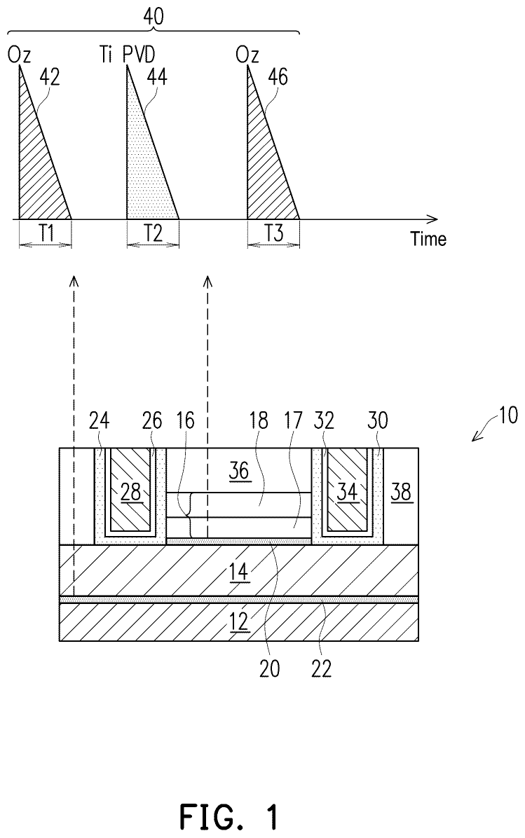

With reference to FIG. 1, a side sectional view of an illustrative FeFET 10 is diagrammatically shown, which beneficially utilizes titanium oxide interface layers formed as disclosed herein. The illustrative FeFET 10 includes a gate electrode 12, a ferroelectric layer 14, and a channel 16 which in the illustrative example includes a bilayer stack including a first channel layer 17 and a second channel layer 18. A first titanium oxide layer 20 is disposed between and contacts each of the ferroelectric layer 14 and the channel 16. A second titanium oxide layer 22 is disposed between and contacts each of the ferroelectric layer 14 and the gate electrode 12. The FeFET 10 further includes a source region including a conductive metal oxide 24, a barrier metal 26, and a source electrode 28; and a drain region including a conductive metal oxide 30, a barrier metal 32, and a drain electrode 34. Dielectric material 36 is disposed over the channel 16, and dielectric material 38 is disposed outside the source and drain regions.

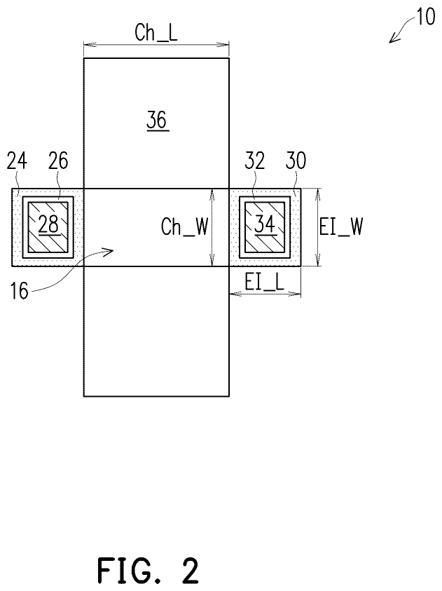

With reference to FIG. 2, a simplified top view of the illustrative FeFET 10 of FIG. 1 is shown, including representation of: the channel 16; the source region including the conductive metal oxide 24, the barrier metal 26, and the source electrode 28; the drain region including the conductive metal oxide 30, the barrier metal 32, and the drain electrode 34; and the dielectric material 36 disposed over the channel 16. Also indicated in FIG. 2 are the channel length Ch_L, the channel width Ch_W, the source/drain electrode length EL_L, and the source/drain electrode width Ch_W. In some nonlimiting illustrative examples: the channel length Ch_L may be in a range of 3 nm to 1,000 nm; the channel width Ch_W may be in a range of 100 nm to 10,000 nm; the electrode length EL_L may be in a range of 30 nm to 10,000 nm; and the electrode width EL_W may be in a range of 100 nm to 10,000 nm. It will be appreciated that these are nonlimiting illustrative example ranges, and that other ranges may be used depending on factors such as the technology node and specific integrated circuit (IC) design.

The ferroelectric layer 14 is made of a ferroelectric material such as HfₓZr₁₋ₓO₂ where 0≤x≤1, or more generally a doped hafnium oxide (HfₓA₁₋ₓO₂) doped with an element A such as zirconium, silicon, aluminum, yttrium, gadolinium, lanthanum, strontium, scandium, titanium, or tantalum, again with 0≤x≤1. These are merely some nonlimiting illustrative examples, and other types of ferroelectric materials are also contemplated for the ferroelectric layer 14.

The channel 16 in the illustrative embodiment includes the illustrative bilayer stack of first channel layer 17 and second channel layer 18. In some nonlimiting illustrative embodiments, the first channel layer 17 may be indium zinc oxide (IZO) and the second channel layer 18 may be indium gallium zinc oxide (InGaZnO), with IZO serving as the major electron transport layer. This is merely an illustrative example, and more generally the channel 16 may comprise one or multiple layers of conductive metal oxide(s) such as ZnO, InO, SnO, InSnO (ITO), fluorine-doped tin oxide (FTO), and/or so forth. Other contemplated materials for the channel 16 include one or more layer comprising InP, GaP, GaN, GaSb, GaAs, AlAs, InAs, InSb, AlGaAs, Si, Ge, SiGe, InGaZnO, InOₓ, GaZnOₓ, InGaSnOₓ, GalInAs, GaInP, InAlAs, InGaAs, AlInGaP, SnOₓ, and/or so forth. Again, these are merely nonlimiting illustrative examples.

Some suitable materials for the conductive metal oxide 24 of the source region and the conductive metal oxide 30 of the drain region include ZnO, InO, IZO, InSnOₓ (ITO), or high electron carrier concentration of InGaZnO. Some suitable materials for the barrier metal 26 of the source region and the barrier metal 32 of the drain region include TiN, WCN, WN, Ta, TaN, Co, CoSiₓ, or so forth. Again, these are merely some nonlimiting illustrative examples.

The gate electrode 12, source electrode 28, and drain electrode 34 are suitably made of a conductive material such as tungsten (W), titanium nitride (TiN), copper (Cu), aluminum (Al), gold (Au), platinum (Pt), or so forth. Again these are merely nonlimiting illustrative examples; moreover, the different electrodes 12, 28, and 34 may in general be made of different materials.

The dielectric material 36 disposed over the channel 16 may for example comprise a low-k dielectric material such as AlOₓ, SiO₂, a-C, Si₃N₄, hydrogen silsesquioxane (HSQ), methylsilsesquioxane (MSQ), or so forth. The dielectric material 38 disposed outside the source and drain regions may be the same material as the dielectric material 36, or may be a different dielectric material.

In the illustrative examples herein, the interface metal oxide layers 20 and 22 are titanium oxide layers, also sometimes denoted herein as TiOₓ layers (where x denotes the titanium-oxygen ratio, i.e., the Ti—O ratio, e.g., TiO₂ has a stoichiometric Ti—O ratio of 1:2). More generally, however, the interface metal oxide layers 20 and 22 may comprise an oxide of another type of metal such as hafnium (Hf), zirconium (Zr), niobium (Nb), or cerium (Ce).

With reference back to FIG. 1, a flow process 40 for forming each of the titanium oxide layers 20 and 22 is also diagrammatically depicted. The process 40 includes an optional initial ozone or ozone plasma exposure 42 of a first layer on which the titanium oxide is to be formed (e.g., the first layer is the ferroelectric layer 14 for formation of the titanium oxide layer 20; or the first layer is the gate electrode layer 12 for formation of the titanium oxide layer 22). This is followed by deposition 44 of a titanium layer on the first layer by physical vapor deposition. This is followed by an ozone or ozone plasma exposure 46 of the titanium layer. The initial ozone or ozone plasma exposure 42 is performed for a time interval T1. The deposition 44 of the titanium layer is performed for a time interval T2. The following ozone or ozone plasma exposure 46 is performed for a time interval T3.

Advantageously, there are numerous process variables of the process 40 which collectively control the thickness and Ti—O ratio of the resulting titanium oxide layer 20 or 22. These process variables include (but are not necessarily limited to): the time intervals T1, T2, and T3; the titanium deposition rate for the deposition 44; the ozone or ozone plasma flow or partial pressure for the exposures 42 and 44; and the process temperature. As the titanium deposition 44 by physical vapor deposition is not a self-limiting process, the thickness of the resulting titanium layer for a given titanium deposition rate R (in units such as angstroms/second) is R×T2. The Ti—O ratio is also continuously controllable for a given ozone or ozone plasma flow or partial pressure by the time interval T3 (and possibly to a lesser extent by time interval T1), together with the thickness of the titanium layer deposited in the deposition 44.

Also advantageously, the process 40 includes only a single cycle of optional ozone or ozone plasma exposure 42 followed by titanium layer deposition 44 followed by ozone or ozone plasma exposure 46. That is, the forming of the titanium oxide layer on the first layer in deposition 44 does not include depositing a further titanium layer after the exposure 46 of the titanium layer to the ozone or ozone plasma. By contrast, forming the titanium oxide layer by atomic layer deposition (ALD) would require N cycles, where N is the number of monolayers making up the titanium oxide layer and each cycle would include self-limiting formation by CVD of a single titanium monolayer (so that there would be N titanium depositions in the N-cycle ALD process).

As previously noted, in the illustrative examples the metal oxide layers 20 and 22 are titanium oxide layers. More generally, each of these layers could comprise another metal oxide, such as hafnium oxide (HfOₓ), zirconium oxide (ZrOₓ), niobium oxide (NbOₓ), or cerium oxide (CeOₓ). For these further nonlimiting examples, the deposition 44 suitably deposits a hafnium (Hf) layer, a zirconium (Zr) layer, a niobium (Nb) layer, or a cerium (Ce) layer, respectively.

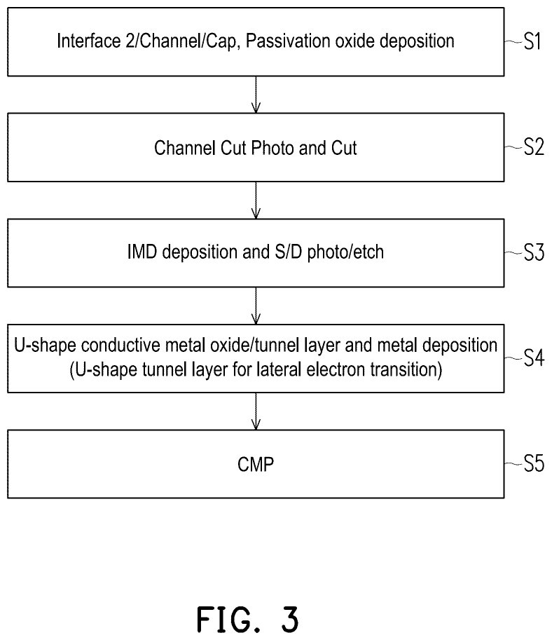

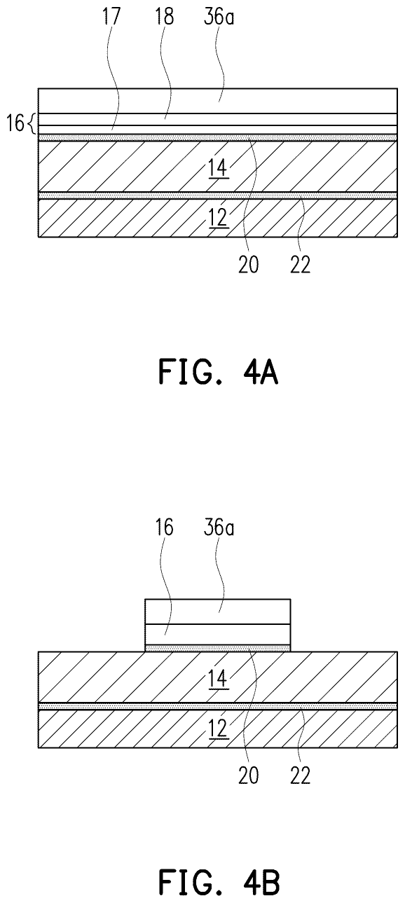

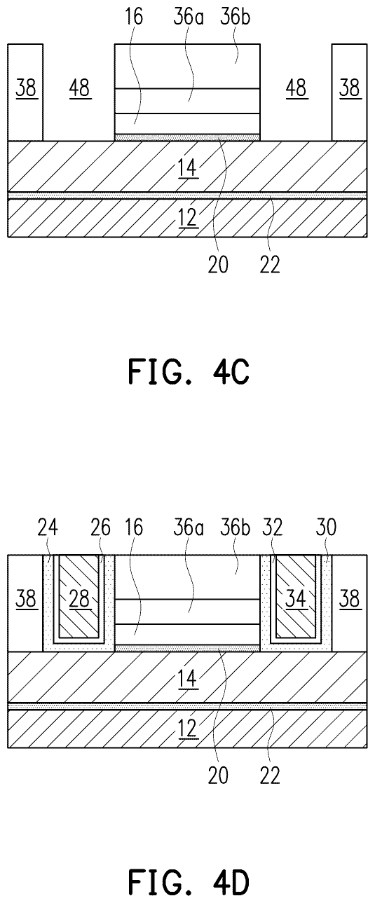

With reference now to FIG. 3 and FIGS. 4A-4D, a suitable process for fabricating the FeFET 10 of FIGS. 1 and 2 is described. FIG. 3 illustrates a flow chart of the process, while FIGS. 4A, 4B, 4C, and 4D diagrammatically illustrate side sectional views of a FeFET-under-fabrication at successive stages of the workflow of FIG. 3. In an operation S1, a layer stack is formed including the gate electrode layer 12, the ferroelectric layer 14, the channel 16, and a first dielectric layer 36a (which will ultimately form a lower portion of the dielectric material 36 disposed over the channel 16). The resulting layer stack is shown in FIG. 4A. Note that FIG. 4A illustrates the channel 16 as including the bilayer stack of lower channel layer 17 and upper channel layer 18; however, subsequent FIGS. 4B-4D will only illustrate the channel 16 without subdivision into the illustrative bilayer stack. The deposition of each of layers 12, 14, 16, and 36a can use any deposition technique suitable for depositing the material of that layer, e.g. chemical vapor deposition (CVD), physical vapor deposition (PVD), plasma deposition, or so forth.

The formation of the first titanium oxide layer 20 disposed between and contacting each of the ferroelectric layer 14 and the channel 16 is suitably formed using the process 40 depicted in FIG. 1, i.e., an optional ozone or ozone plasma exposure 42 of the ferroelectric layer 14, followed by deposition of a titanium layer on the ferroelectric layer 14 by physical vapor deposition, followed by an ozone or ozone plasma exposure 46 of the titanium layer to oxidize the titanium layer to form TiOₓ.

The formation of the second titanium oxide layer 22 disposed between and contacting each of the ferroelectric layer 14 and the gate electrode 12 is also suitably formed using the process 40 depicted in FIG. 1, i.e., an optional ozone or ozone plasma exposure 42 of the gate electrode layer 12, followed by deposition of a titanium layer on the gate electrode layer 12 by physical vapor deposition, followed by an ozone or ozone plasma exposure 46 of the titanium layer to oxidize the titanium layer to form TiOₓ.

With continuing reference to FIG. 3 and with further reference to FIG. 4B, in an operation S2 photolithography is used to define and cut the channel, producing the structure shown in FIG. 4B in which the channel 16, titanium oxide layer 20, and overlying first dielectric layer 36a are patterned.

With continuing reference to FIG. 3 and with further reference to FIG. 4C, in an operation S3 intermetal dielectric (IMD) deposition is performed to deposit an upper portion 36b of the overlying dielectric layer 36 and the dielectric material 38, and these layers are patterned to form openings 48 corresponding to the source and drain regions. The resulting structure is shown in FIG. 4C.

With continuing reference to FIG. 3 and with further reference to FIG. 4D, in an operation S4 the U-shaped conductive metal oxide layers 24 and 30 of the source and drain regions, respectively, are deposited to line the interior surfaces of the openings 48; followed by deposition of the barrier metal layers 26 and 32 of the source and drain regions, respectively, on the corresponding metal oxide layers 24 and 30. The U-shaped tunnel layer provides for lateral electron transition. This is followed by filling the remainder of the openings 48 with tungsten or other electrically conductive material (e.g., TiN, Cu, Al, Au, Pt, or so forth) to form the source electrode 28 and drain electrode 34. Formation of these electrodes 28 and 34 may overfill the openings 48—hence, a final chemical-mechanical polish (CMP) operation S5 is performed to planarize the surface of the FeFET, thus producing the final FeFET shown in FIG. 4D.

FeFET test devices having the structure described with reference to FIGS. 1 and 2 were fabricated according to the workflow described with reference to FIGS. 3 and 4A-4D. In the FeFET test devices, the ferroelectric layer was Hf_{0.5}Zr_{0.5}O₂ (HZO) with a thickness of about 75-80 angstroms, the first channel layer 17 was InZnO (IZO), and the second channel layer 18 was InGaZnO, with a total channel thickness in a range of about 35-50 angstroms. These FeFET test devices were fabricated with different values of the variables of the process 40 used to form the titanium oxide layers 20 and 22. FeFET test devices were fabricated with: the time T1 of the first ozone exposure 42 in a range between 0.1 second and 30 seconds; the time T3 of the second ozone exposure 46 in a range between 0.1 second and 30 seconds; deposition temperature in a range of about 150° C. to 500° C.; and the time T2 of the titanium layer deposition was effective to produce the titanium layer with a thickness in the range of about 0.1 angstrom to about 30 angstroms (where sub-monolayer thickness values correspond to fractional monolayer).

The test results indicated that lower temperatures for forming the titanium oxide 20 and a shorter times T3 for the second ozone exposure 46 led to a larger memory window (MW) of up to about 1 volt, and higher 2Pr values of about 15 μC/cm², and large FeFET endurance values of greater than 1 million cycles. Reducing the second ozone exposure time T3 from 9 seconds to 3 seconds was found to predominantly increase Ion. Table 1 summarizes tuning rules derived from the FeFET test devices.

TABLE 1

| Process variable | Value range | Device performance tuning |
|---|---|---|
| First ozone exposure 42 | 1 sec to 30 sec | 2Pr (about 3-15 μC/cm²) |
| | | MW (about 0.1 to 1 volt) |
| Temperature for PVD titanium | 150° C. to 500° C. | 2Pr (about 3-15 μC/cm²) |
| layer deposition 44 | | MW (about 0.1 to 1 volt) |
| PVD titanium thickness | 0.1 angstrom to | Endurance (1E6-1E9 cycles) |
| | 30 angstroms | |
| Second ozone exposure 46 | 1 sec to 30 sec | Ion (50 to 200 μA/μm) |

For a FeFET higher MW and 2Pr values are desirable, higher Ion is desirable, and greater endurance is desirable. Based on the results for the FeFET test devices, a preferred range for the PVD-deposited titanium layer thickness was about 0.1 angstroms to 10 angstroms, with a preferred deposition temperature of 300° C. or less. The time T1 of the first ozone exposure 42 was found to be at least 3 seconds. The time T3 for the second ozone exposure 46 was found to be in a range of about 1 second to about 6 seconds to improve Ion.

It is noted that the FeFET test devices are for a specific FeFET configuration shown in FIGS. 1 and 2, and that these optimal process variable value ranges for the process 40 of FIG. 1 may be differently optimized for other types of FeFET transistor configurations, and for different TFT transistors. It is straightforward to optimize the controllable variables (e.g., times T1, T2, and T3 and titanium oxide formation temperature) for a given transistor design by fabricating test devices for a matrix of values of these parameters and performing measurements of relevant device parameters such as Ion, MW, 2Pr, and endurance.

Furthermore, to examine the composition of the titanium oxide films produced by the process 40 shown in FIG. 1, titanium oxide layers deposited on silicon dioxide were examined by X-ray photoelectron spectroscopy (XPS), which indicated the process 40 can be tuned to form a stoichiometric TiO₂ layer.

With reference now to FIGS. 5-11, some further examples of FeFET and TFT transistors that can beneficially employ titanium oxide layers formed using the process 40 of FIG. 1 are diagrammatically illustrated. Each of the illustrative transistors is formed on a substrate 49, and includes a gate electrode G, a source electrode S, and a drain electrode D, as well as a channel 16. The gate electrode G, source electrode S, and drain electrode D are suitably made of a conductive material such as tungsten (W), titanium nitride (TiN), copper (Cu), aluminum (Al), gold (Au), platinum (Pt), or so forth. Again these are merely nonlimiting illustrative examples; moreover, the different electrodes G, S, and D may in general be made of different materials. The channel 16 may in general comprise any suitable carrier transport material, such as indium-gallium-zinc-oxide (IGZO), Si, Ge, C, SiC, SiGe, SiGeC, GaAs, InP, GaP, GaN, GaSb, GaAs, AlAs, InAs, InSb, AlGaAs, GaInAs, GaInP, InAlAs, InGaAs, AlInGaP, CdS, CdSe, CdTe, ZnS, ZnSe, ZnTe, PbS, PbTe, HgTe, et cetera. These are merely some nonlimiting illustrative examples, and other types of channel materials are also contemplated for the channel 16.

With particular reference to FIG. 5, a bottom-gate thin-film transistor (TFT) 50 is shown. The bottom-gate TFT 50 includes a bottom gate dielectric layer 52 which may for example comprise silicon dioxide (SiO₂) or a high-k dielectric material such as HfO₂, Zr-doped HfO₂, Al-doped HfO₂, or so forth. These are merely some nonlimiting illustrative examples, and other types of high-k dielectric materials are also contemplated for the bottom gate dielectric layer 52. A titanium oxide layer 54 is disposed between and contacts both the channel 16 and the gate dielectric layer 52, and hence functionally corresponds to the titanium oxide layer 20 of the FeFET of FIGS. 1 and 2. An additional titanium oxide layer 56 is disposed between and contacts both the channel 16 and the source electrode S, and an additional titanium oxide layer 58 is disposed between and contacts both the channel 16 and the drain electrode D. Each of the titanium oxide layers 54, 56, and 58 may be formed using the process 40 diagrammatically depicted in FIG. 1.

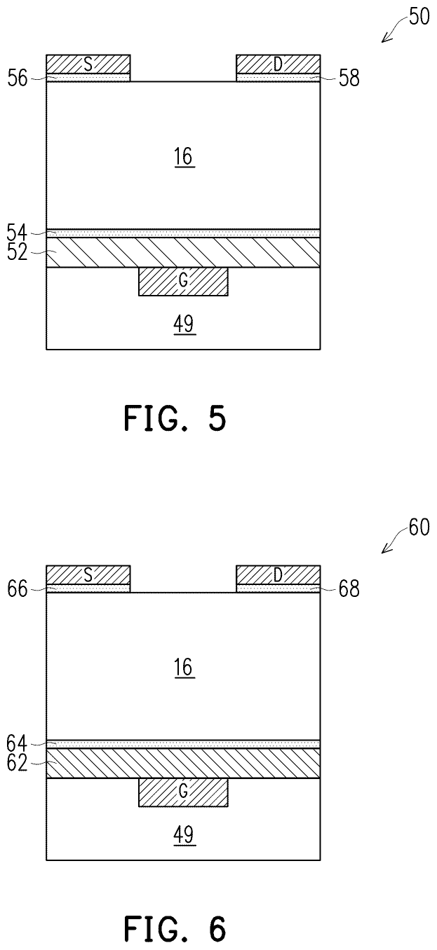

With particular reference to FIG. 6, a bottom-gate FeFET 60 is shown. The bottom-gate FeFET 60 includes a bottom ferroelectric layer 62 which comprises a ferroelectric material such as HfₓZr₁₋ₓO₂ where 0≤x≤1, or hafnium oxide (HfₓA₁₋ₓO₂) doped with an element A such as zirconium, silicon, aluminum, yttrium, gadolinium, lanthanum, strontium, scandium, titanium, or tantalum, again with 0≤x≤1. These are merely some nonlimiting illustrative examples, and other types of ferroelectric materials are also contemplated for the ferroelectric layer 62. A titanium oxide layer 64 is disposed between and contacts both the channel 16 and the bottom ferroelectric layer 62, and hence functionally corresponds to the titanium oxide layer 20 of the FeFET of FIGS. 1 and 2. An additional titanium oxide layer 66 is disposed between and contacts both the channel 16 and the source electrode S, and an additional titanium oxide layer 68 is disposed between and contacts both the channel 16 and the drain electrode D. Each of the titanium oxide layers 64, 66, and 68 may be formed using the process 40 diagrammatically depicted in FIG. 1.

With particular reference to FIG. 7, a top-gate TFT 70 is shown. The top-gate TFT 70 includes a top gate dielectric layer 72 which is disposed on the channel 16, and which may for example comprise SiO₂ or a high-k dielectric material such as HfO₂, Zr-doped HfO₂, Al-doped HfO₂, or so forth. These are merely some nonlimiting illustrative examples, and other types of high-k dielectric materials are also contemplated for the top gate dielectric layer 72. A titanium oxide layer 74 is disposed between and contacts both the channel 16 and the gate dielectric layer 72. The titanium oxide layer 74 also extends between and contacts both the source electrode S and the gate dielectric layer 72. The titanium oxide layer 74 also extends between and contacts both the drain electrode D and the gate dielectric layer 72. The titanium oxide layer 74 may be formed using the process 40 diagrammatically depicted in FIG. 1.

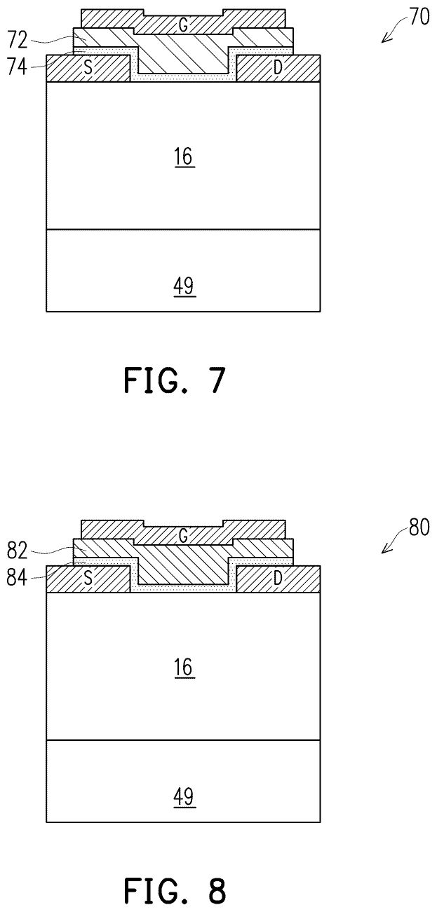

With particular reference to FIG. 8, a top-gate FeFET 80 is shown. The top-gate FeFET 80 includes a top ferroelectric layer 82 which is disposed on the channel 16, and which comprises a ferroelectric material such as HfₓZr₁₋ₓO₂ where 0≤x≤1, or hafnium oxide (HfₓA₁₋ₓO₂) doped with an element A such as zirconium, silicon, aluminum, yttrium, gadolinium, lanthanum, strontium, scandium, titanium, or tantalum, again with 0≤x≤1. These are merely some nonlimiting illustrative examples, and other types of ferroelectric materials are also contemplated for the ferroelectric layer 82. A titanium oxide layer 84 is disposed between and contacts both the channel 16 and the ferroelectric layer 82. The titanium oxide layer 84 also extends between and contacts both the source electrode S and the ferroelectric layer 82. The titanium oxide layer 84 also extends between and contacts both the drain electrode D and the ferroelectric layer 82. The titanium oxide layer 84 may be formed using the process 40 diagrammatically depicted in FIG. 1.

With particular reference to FIG. 9, a double-gate TFT 90 is shown. The double-gate TFT 70 includes both a top layer 92 which is disposed on the channel 16, and a bottom layer 94 which is disposed below the channel 16. Each of the top layer 92 and the bottom layer 94 may for example comprise SiO₂ or a high-k gate dielectric material such as HfO₂, Zr-doped HfO₂, Al-doped HfO₂, or so forth. These are merely some nonlimiting illustrative examples, and other types of high-k dielectric materials are also contemplated for the layers 92 and 94. The top layer 92 is contacted by a top gate electrode TG and the bottom layer 94 is contacted by a bottom gate electrode BG. At the device level the top and bottom gate electrodes TG and BG may optionally be electrically connected. A titanium oxide layer 96 is disposed between and contacts both the channel 16 and the bottom gate 94. Another titanium oxide layer 98 is disposed between and contacts both the channel 16 and the top gate 92. The titanium oxide layer 98 also extends over the source electrode S, and over the drain electrode D. The titanium oxide layers 96 and 98 may each be formed using the process 40 diagrammatically depicted in FIG. 1.

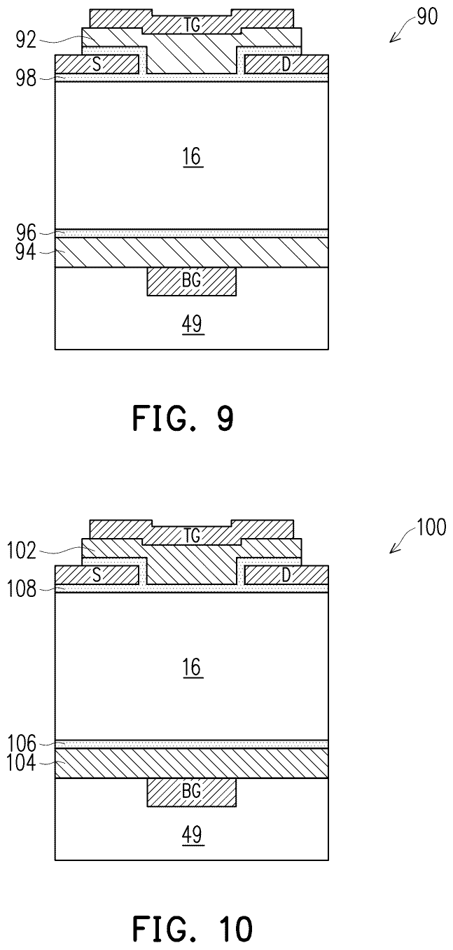

With particular reference to FIG. 10, a double-gate FeFET 100 is shown. The double-gate FeFET 100 includes both a top ferroelectric layer 102 which is disposed on the channel 16, and a bottom ferroelectric layer 104 which is disposed below the channel 16. Each of the top ferroelectric layer 102 and the bottom ferroelectric layer 104 comprises a ferroelectric material such as HfₓZr₁₋ₓO₂ where 0≤x≤1, or hafnium oxide (HfₓA₁₋ₓO₂) doped with an element A such as zirconium, silicon, aluminum, yttrium, gadolinium, lanthanum, strontium, scandium, titanium, or tantalum, again with 0≤x≤1. These are merely some nonlimiting illustrative examples, and other types of ferroelectric materials are also contemplated for the ferroelectric layers 102 and 104. The top ferroelectric layer 102 is contacted by a top gate electrode TG and the bottom ferroelectric layer 104 is contacted by a bottom gate electrode BG. At the device level the top and bottom gate electrodes TG and BG may optionally be electrically connected. A titanium oxide layer 106 is disposed between and contacts both the channel 16 and the bottom ferroelectric layer 104. Another titanium oxide layer 108 is disposed between and contacts both the channel 16 and the top ferroelectric layer 102. The titanium oxide layer 108 also extends over the source electrode S, and over the drain electrode D. The titanium oxide layers 106 and 108 may each be formed using the process 40 diagrammatically depicted in FIG. 1.

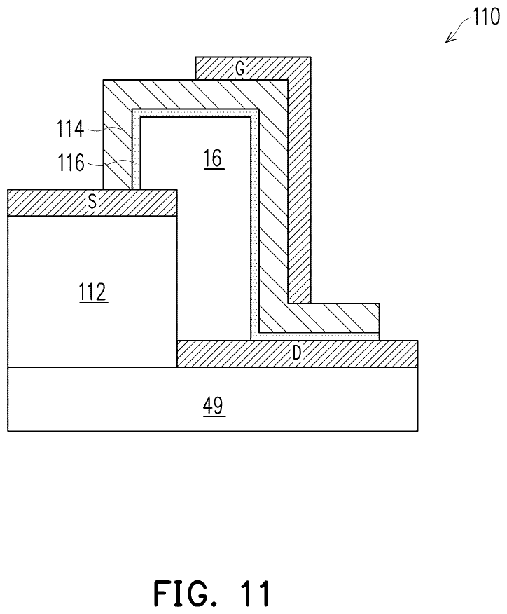

With particular reference to FIG. 11, a three-dimensional (3D) or vertical device 110 is shown, which may be a TFT or an FeFET. The device 110 includes a 3D or vertical channel 16 supported on one side by an oxide 112. A layer 114 is disposed over the top and sides of the channel 16, with a titanium oxide layer 116 disposed between and contacting each of the channel 16 and the layer 114. In embodiments in which the device 110 is a TFT, the layer 114 suitably comprises a gate dielectric layer such as SiO₂ or a high-k dielectric material such as HfO₂, Zr-doped HfO₂, Al-doped HfO₂, or so forth. These are merely some nonlimiting illustrative examples, and other types of high-k dielectric materials are also contemplated for the layer 114. In embodiments in which the device 110 is a FeFET, the layer 114 is suitably a ferroelectric material such as HfₓZr₁₋ₓO₂ where 0≤x≤1, or hafnium oxide (HfₓA₁₋ₓO₂) doped with an element A such as zirconium, silicon, aluminum, yttrium, gadolinium, lanthanum, strontium, scandium, titanium, or tantalum, again with 0≤x≤1. These are merely some nonlimiting illustrative examples, and other types of ferroelectric materials are also contemplated. The titanium oxide layer 116 may be formed using the process 40 diagrammatically depicted in FIG. 1.

More generally, for various device embodiments employing one or more titanium oxide interface layers (of which the devices of FIGS. 1-2 and 5-11 are nonlimiting illustrative examples), the gate dielectric layer or ferroelectric layer (e.g., ferroelectric layers 14, 62, 82, 102, 104, 114 or gate dielectric layers 52, 72, 92, 94, 114 in various nonlimiting illustrative embodiments described herein) may comprise HfOₓ, ZrOₓ, LaHfOₓ, LaHfZrO, La₂O₃, HfSiO, HfAlO, HfNO, ErTiO₅, SrTiO₃, LaScO₃, LaAlO₃, GdScO₃, LaLuO₃, La₂Hf₂O₇, Gd₂O₃, La₂SiO₅, SrHfO₃, Ce—Oₓ, BeOₓ, InOₓ, GaOₓ, AlOₓ, SnOₓ, VOₓ, WOₓ, TiOₓ, ZrOₓ, NbOₓ, HfOₓ, SiOₓ, or TaOₓ. The channel may in general comprise any suitable carrier transport material, such as indium-gallium-zinc-oxide (IGZO), Si, Ge, C, SiC, SiGe, SiGeC, GaAs, InP, GaP, GaN, GaSb, GaAs, AlAs, InAs, InSb, AlGaAs, GaInAs, GaInP, InAlAs, InGaAs, AlInGaP, CdS, CdSe, CdTe, ZnS, ZnSe, ZnTe, PbS, PbTe, HgTe, et cetera. While a titanium oxide interface layer (or layers) are described by way of illustrative example, more generally the interface layer may be a metal oxide interface layer formed by depositing a metal layer by PVD and converting the metal layer to a metal oxide layer. For example, the metal oxide layer may be formed by an optional ozone or ozone plasma exposure followed by depositing a metal layer by PVD followed by an ozone or ozone plasma exposure of the metal layer. The metal layer may be, for example, a hafnium (Hf) layer, a zirconium (Zr) layer, a niobium (Nb) layer, a cerium (Ce) layer, or so forth.

The disclosed transistors may be employed in substantially any type of transistor circuit, such as by way of some nonlimiting illustrative examples a dynamic random access memory (DRAM) circuit, a static random access memory (SRAM) circuit, an FeRAM 1T-1C ferroelectric capacitor structure, and/or so forth.

In the following, some further embodiments are described.

In a nonlimiting illustrative embodiment, a method of fabricating a ferroelectric field effect transistor (FeFET) includes: forming a first layer which is one of a ferroelectric layer or a channel of the FeFET; forming a metal oxide layer on the first layer by depositing a metal layer on the first layer by physical vapor deposition followed by exposing the metal layer to ozone or ozone plasma; and forming a second layer on the metal oxide layer wherein the second layer is the other of the ferroelectric layer or the channel of the FeFET.

In a nonlimiting illustrative embodiment, a ferroelectric field effect transistor (FeFET) includes a ferroelectric layer, a channel, and a titanium oxide layer disposed between and in contact with each of the ferroelectric layer and the channel. The FeFET has an on current (Ion) of at least 50 microamperes per micron.

In a nonlimiting illustrative embodiment, a method of fabricating a FeFET includes: forming a ferroelectric layer; forming a titanium oxide layer on the ferroelectric layer by depositing a titanium layer on the ferroelectric layer by physical vapor deposition followed by exposing the titanium layer to ozone or ozone plasma; and forming a channel layer on the titanium oxide layer. In some such embodiments, the method further includes forming a gate electrode and forming a titanium oxide layer on the gate electrode by depositing a titanium layer on the gate electrode by physical vapor deposition followed by exposing the titanium layer to ozone or ozone plasma; wherein the ferroelectric layer is formed on the titanium layer that is formed on the gate electrode. In some embodiments, in the forming of the titanium oxide layer on the ferroelectric layer: the titanium layer deposited on the ferroelectric layer by physical vapor deposition has a thickness of 30 angstroms or less; the titanium layer deposited on the ferroelectric layer is exposed to the ozone or ozone plasma for a time period in the range 0.1 second to 30 seconds; and the forming of the titanium oxide layer on the ferroelectric layer is performed at a temperature of 300 degrees Celsius or less.

In a nonlimiting illustrative embodiment, a method of fabricating a transistor includes: forming a first layer which is one of a gate dielectric layer or a channel of the transistor; forming a metal oxide layer on the first layer by depositing a metal layer on the first layer by physical vapor deposition followed by exposing the metal layer to ozone or ozone plasma; and forming a second layer on the metal oxide layer wherein the second layer is the other of the gate dielectric layer or the channel of the transistor. The forming of the metal oxide layer may further include, prior to the depositing of the metal layer, exposing the first layer to ozone or ozone plasma. The metal layer may be a titanium layer.

In a nonlimiting illustrative embodiment, a method of fabricating a device includes forming a first layer. The first layer may be a ferroelectric layer if the device is a ferroelectric field effect transistor (FeFET), or a gate dielectric layer if the device is a transistor. Alternatively, the first layer may be a channel of the device. A metal oxide layer is formed on the first layer by depositing a metal layer on the first layer by physical vapor deposition followed by exposing the metal layer to ozone or ozone plasma. A second layer is formed on the metal oxide layer. The forming of the metal oxide layer may further include, prior to the depositing of the metal layer, exposing the first layer to ozone or ozone plasma. The metal layer may be a titanium layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a ferroelectric field effect transistor (FeFET), the method comprising:
forming a first layer which is one of a ferroelectric layer or a channel of the FeFET;
forming a metal oxide layer on the first layer by depositing a metal layer on the first layer by physical vapor deposition followed by exposing the metal layer to ozone or ozone plasma; and
forming a second layer on the metal oxide layer wherein the second layer is the other of the ferroelectric layer or the channel of the FeFET.

2. The method of claim 1, wherein the forming of the metal oxide layer further includes, prior to the depositing of the metal layer, exposing the first layer to ozone or ozone plasma.

3. The method of claim 1, wherein the metal layer is a titanium layer.

4. The method of claim 1, wherein the metal layer has a thickness in a range of 10 angstroms or less.

5. The method of claim 1, wherein the metal layer is exposed to the ozone or ozone plasma for a time period in the range 0.1 second to 30 seconds.

6. The method of claim 1, wherein the forming of the metal oxide layer is performed at a temperature of 300 degrees Celsius or less.

7. The method of claim 1, wherein the forming of the metal oxide layer on the first layer does not include depositing a further metal layer after the exposure of the metal layer to the ozone or ozone plasma.

8. The method of claim 1, wherein the first layer is the ferroelectric layer of the FeFET and the second layer is the channel of the FeFET.

9. The method of claim 8, wherein the ferroelectric layer is HfₓZr₁₋ₓO₂ where 0≤x≤1, or a doped hafnium oxide (HfₓA₁₋ₓO₂) where 0≤x≤1, and element A is selected from the group consisting of zirconium, silicon, aluminum, yttrium, gadolinium, lanthanum, strontium, scandium, titanium, or tantalum.

10. The method of claim 8, further comprising:
prior to forming the ferroelectric layer of the FeFET, forming a gate electrode; and
prior to forming the ferroelectric layer of the FeFET, forming a second metal oxide layer on the gate electrode by depositing a second metal layer on the gate electrode by physical vapor deposition followed by exposing the second metal layer to ozone or ozone plasma.

11. The method of claim 8, further comprising:
forming a second metal oxide layer on the channel of the FeFET by depositing a metal layer on the channel by physical vapor deposition followed by exposing the metal layer to ozone or ozone plasma.

12. The method of claim 11, further comprising:
forming source and drain regions of the FeFET on the second metal oxide layer.

13. The method of claim 11, further comprising:
forming a second ferroelectric layer on the second metal oxide layer.

14. The method of claim 1, wherein the first layer is the channel of the FeFET and the second layer is the ferroelectric layer of the FeFET.

15. The method of claim 14, wherein the metal oxide layer is formed on a top and sides of the channel.

16. A ferroelectric field effect transistor (FeFET) comprising:
a ferroelectric layer;
a channel; and
a titanium oxide layer disposed between and in contact with each of the ferroelectric layer and the channel;
wherein the FeFET has an on current (Ion) of at least 50 microamperes per micron.

17. The FeFET of claim 16, further comprising:
a gate electrode; and
a second titanium oxide layer disposed between and in contact with each of the ferroelectric layer and the gate electrode.

18. A method of fabricating a transistor, the method comprising:
forming a first layer which is one of a gate dielectric layer or a channel of the transistor;
forming a metal oxide layer on the first layer by depositing a metal layer on the first layer by physical vapor deposition followed by exposing the metal layer to ozone or ozone plasma; and
forming a second layer on the metal oxide layer wherein the second layer is the other of the gate dielectric layer or the channel of the transistor.

19. The method of claim 18, wherein the forming of the metal oxide layer further includes, prior to the depositing of the metal layer, exposing the first layer to ozone or ozone plasma.

20. The method of claim 18, wherein the metal layer is a titanium layer.
